(19) United States
(12) Patent Application Publication
(10) Pub. No.: US 2023/0418334 A1
(43) Pub. Date: Dec. 28, 2023

(54) FLEXIBLE ELECTRONIC DEVICE

(71) Applicant: InnoLux Corporation, Miao-Li County (TW)

(72) Inventors: Yuan-Lin WU, Miao-Li County (TW); Kuan-Feng LEE, Miao-Li County (TW)

(73) Assignee: InnoLux Corporation, Miao-Li County (TW)

(21) Appl. No.: 18/197,103

(22) Filed: May 15, 2023

(30) Foreign Application Priority Data
Jun. 22, 2022 (CN) 202210714139.7

(51) Int. Cl. G06F 1/16; H04M 1/02

(52) U.S. Cl. CPC G06F 1/1652; H04M 1/0268; G06F 1/1656; G06F 1/1616; H04M 1/0216

(57) ABSTRACT

A flexible electronic device is disclosed by this disclosure. The flexible electronic device includes a supporting layer, a flexible layer, a medium layer, and electronic elements. The flexible layer is disposed on the supporting layer, and the flexible layer includes at least two main portions and a deformable portion connecting the two main portions. The medium layer is disposed between the supporting layer and the flexible layer, and the medium layer includes a first portion located under the deformable portion and a second portion located under one of the two main portions. The electronic elements are disposed on the two main portions, and a thickness of the first portion is less than a thickness of the second portion.

### BACKGROUND OF THE DISCLOSURE

### 1. Field of the Disclosure

The present disclosure relates to an electronic device, and particularly to a flexible electronic device.

### 2. Description of the Prior Art

The flexible electronic device may be fixed to a curved surface by stretching and/or bending the electronic device. For example, the flexible electronic device may be attached to curved surfaces such as skin, car panel, curved glass, and the like. Therefore, the flexible electronic device may serve as biosensors, electronic elements in car, or may be used for other suitable purposes. As user requirements for flexible electronic devices become higher, how to improve the reliability of flexible electronic device is still an important issue in the related field.

### SUMMARY OF THE DISCLOSURE

It is one of the objectives of the present disclosure to provide a flexible electronic device. The product reliability of the flexible electronic device is improved by a medium layer including portions with different thicknesses.

In some embodiments, a flexible electronic device is provided in this disclosure. The flexible electronic device includes a supporting layer, a flexible layer, a medium layer, and electronic elements. The flexible layer is disposed on the supporting layer, and the flexible layer includes at least two main portions and a deformable portion connecting the at least two main portions. The medium layer is disposed between the supporting layer and the flexible layer, and the medium layer includes a first portion located under the deformable portion and a second portion located under one of the at least two main portions. The electronic elements are disposed on the at least two main portions. A thickness of the first portion is less than a thickness of the second portion.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1A is a schematic diagram illustrating an electronic device according to an embodiment of the present disclosure.

FIG. 1B is a schematic diagram illustrating the electronic device when the electronic device is folded according to an embodiment of the present disclosure.

FIG. 2A is a schematic diagram illustrating an electronic device before and after deformation according to another embodiment of the present disclosure.

FIG. 2B is a schematic diagram illustrating an electronic device before and after deformation according to further another embodiment of the present disclosure.

FIG. 2C is a schematic diagram of the relationship between a thickness design of a medium layer in the electronic device and damage rate according to an embodiment of the present disclosure.

FIG. 3A, FIG. 3B, and FIG. 3C are schematic diagrams illustrating a manufacturing method of an electronic device according to a first embodiment of the present disclosure, wherein FIG. 3B is a schematic drawing in a step subsequent to FIG. 3A, and FIG. 3C is a schematic drawing in a step subsequent to FIG. 3B.

FIG. 4A is a top view schematic diagram illustrating a partial area of the electronic device according to the first embodiment of the present disclosure.

FIG. 4B is a top view schematic diagram illustrating a supporting layer and a medium layer of the electronic device according to the first embodiment of the present disclosure.

FIG. 4C is a cross-sectional schematic diagram of the electronic device taken along a line A-A′ in FIG. 4A according to the first embodiment of the present disclosure.

FIG. 5A and FIG. 5B are schematic diagrams illustrating a manufacturing method of an electronic device according to a second embodiment of the present disclosure, wherein FIG. 5B is a schematic drawing in a step subsequent to FIG. 5A.

FIG. 6A is a top view schematic diagram illustrating a supporting layer and a medium layer of the electronic device according to the second embodiment of the present disclosure.

FIG. 6B is a cross-sectional schematic diagram of the electronic device according to the second embodiment of the present disclosure.

FIG. 7A and FIG. 7B are schematic diagrams illustrating a manufacturing method of an electronic device according to a third embodiment of the present disclosure, wherein FIG. 7B is a schematic drawing in a step subsequent to FIG. 7A.

FIG. 8A is a top view schematic diagram illustrating a supporting layer and a medium layer of the electronic device according to the third embodiment of the present disclosure.

FIG. 8B is a cross-sectional schematic diagram of the electronic device according to the third embodiment of the present disclosure.

FIG. 9A is a top view schematic diagram illustrating a supporting layer and a medium layer of an electronic device according to a fourth embodiment of the present disclosure.

FIG. 9B is a schematic diagram illustrating a manufacturing method of the electronic device according to the fourth embodiment of the present disclosure,

FIG. 10A is a cross-sectional schematic diagram of an electronic device according to a fifth embodiment of the present disclosure.

FIG. 10B is a top view schematic diagram illustrating the electronic device according to the fifth embodiment of the present disclosure.

FIG. 11A is a cross-sectional schematic diagram of an electronic device according to a sixth embodiment of the present disclosure.

FIG. 11B is a top view schematic diagram illustrating the electronic device according to the sixth embodiment of the present disclosure.

FIG. 12A and FIG. 12B are schematic diagrams illustrating a manufacturing method of an electronic device according to a seventh embodiment of the present disclosure, wherein FIG. 12B is a schematic drawing in a step subsequent to FIG. 12A.

FIG. 13A is a cross-sectional schematic diagram of an electronic device according to an eighth embodiment of the present disclosure.

FIG. 13B is a cross-sectional schematic diagram of an electronic device according to a ninth embodiment of the present disclosure.

FIG. 13C is a cross-sectional schematic diagram of an electronic device according to a tenth embodiment of the present disclosure.

FIG. 13D is a cross-sectional schematic diagram of an electronic device according to an eleventh embodiment of the present disclosure.

### DETAILED DESCRIPTION

The present disclosure may be understood by referring to the following detailed description, taken in conjunction with the drawings as described below. It is noted that, for purposes of illustrative clarity and being easily understood by the readers, various drawings of this disclosure show a portion of the electronic device, and certain elements in various drawings may not be drawn to scale. In addition, the number and dimension of each element shown in drawings are only illustrative and are not intended to limit the scope of the present disclosure.

Certain terms are used throughout the description and following claims to refer to particular elements. As one skilled in the art will understand, electronic equipment manufacturers may refer to an element by different names. This document does not intend to distinguish between elements that differ in name but not function.

In the following description and in the claims, the terms “include”, “comprise” and “have” are used in an open-ended fashion, and thus should be interpreted to mean “include, but not limited to . . . ”.

It will be understood that when an element or a layer is referred to as being “disposed on” or “connected to” another element or layer, it can be directly on or directly connected to the other element or layer, or intervening elements or layers may be presented (indirectly). In contrast, when an element is referred to as being “directly on” or “directly connected to” another element or layer, there are no intervening elements or layers presented. When an element or a layer is referred to as being “coupled” to another element or layer, it can be a direct electrical connection or an indirect electrical connection. In the case of a direct connection, the ends of the elements on two circuits are directly connected or connected to each other by a conductor segment. In the case of an indirect connection, switches, diodes, capacitors, inductors, resistors, other suitable elements or combinations of the above elements may be included between the ends of the elements on two circuits, but not limited thereto.

Although terms such as first, second, third, etc., may be used to describe diverse constituent elements, such constituent elements are not limited by the terms. The terms are used only to discriminate a constituent element from other constituent elements in the specification. The claims may not use the same terms, but instead may use the terms first, second, third, etc. with respect to the order in which an element is claimed. Accordingly, in the following description, a first constituent element may be a second constituent element in a claim.

In addition, any two values or directions used for comparison may have certain errors. In addition, the terms “equal to”, “equal”, “the same”, “approximately” or “substantially” are generally interpreted as being within ±10%, ±5%, ±3%, ±2%, ±1%, or ±0.5% of the given value.

Unless it is additionally defined, all terms (including technical and scientific terms) used herein have the same meaning as commonly understood by those ordinary skilled in the art. It can be understood that these terms that are defined in commonly used dictionaries should be interpreted as having meanings consistent with the relevant art and the background or content of the present disclosure, and should not be interpreted in an idealized or overly formal manner, unless it is specifically defined in the embodiments of the present disclosure.

The electronic device of the present disclosure may include a display device, a sensing device, a backlight device, an antenna device, a tiled device or other suitable electronic devices, but not limited thereto. The electronic device may be a foldable electronic device, a flexible electronic device or a stretchable electronic device. For example, the electronic device of the present disclosure may include a flexible electronic device. The display device may for example be applied to laptops, public displays, tiled displays, vehicle displays, touch displays, televisions, monitors, smart phones, tablets, light source modules, lighting devices or electronic devices applied to the products mentioned above, but not limited thereto. The sensing device may for example include a light sensor, a biosensor, a touch sensor, a fingerprint sensor, other suitable sensors or combinations of the above-mentioned sensors. The antenna device may for example include a liquid crystal antenna device, but not limited thereto. The tiled device may for example include a tiled display device or a tiled antenna device, but not limited thereto. In addition, the outline of the electronic device may be a rectangle, a circle, a polygon, a shape with curved edge or other suitable shapes. The electronic device may include electronic elements, wherein the electronic elements may include passive elements or active elements, such as capacitors, resistors, inductors, diodes, transistors, sensors, and the like. The diode may include a light emitting diode or a photo diode. The light emitting diode may for example include an organic light emitting diode (OLED) or an in-organic light emitting diode. The in-organic light emitting diode may for example include a mini light emitting diode (mini LED), a micro light emitting diode (micro LED) or a quantum dot light emitting diode (quantum dot LED), but not limited thereto. The electronic device may include peripheral systems such as driving systems, control systems, light source systems, shelf systems, and the like for supporting the display device, the antenna device or the tiled device. It should be noted that the electronic device of the present disclosure may be combinations of the above-mentioned devices, but not limited thereto. The display device is taking as an example to describe the contents of the present disclosure in the following, but the present disclosure is not limited thereto.

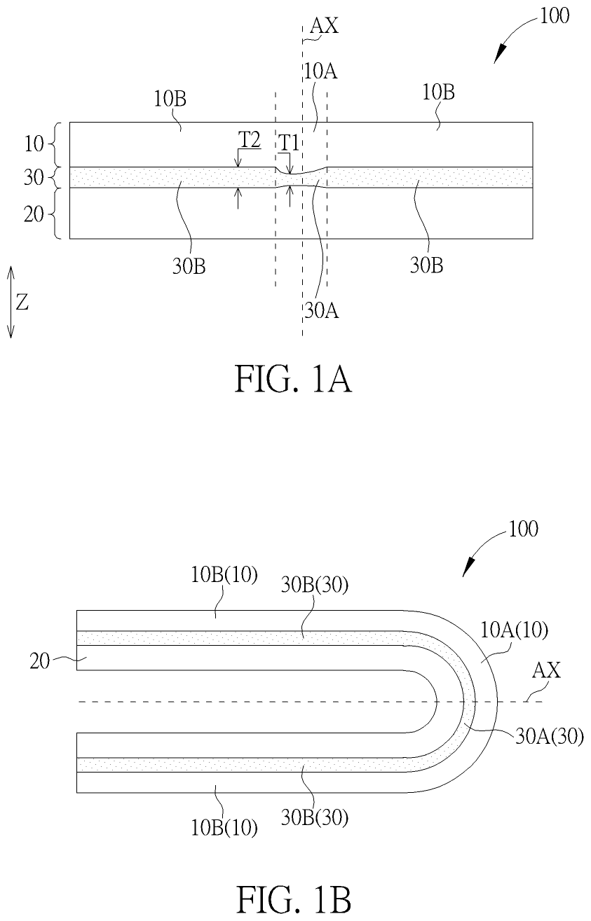

Please refer to FIG. 1A and FIG. 1B. FIG. 1A is a schematic diagram illustrating an electronic device 100 according to an embodiment of the present disclosure, and FIG. 1B is a schematic diagram illustrating the electronic device 100 when the electronic device 100 is folded. As shown in FIG. 1A, the electronic device 100 may include a supporting layer 20, a flexible layer 10, and a medium layer 30. The flexible layer 10 is disposed on the supporting layer 20. The flexible layer 10 includes at least two main portions 10B and a deformable portion 10A connecting the two main portions 10B. The medium layer 30 is disposed between the supporting layer 20 and the flexible layer 10, and the medium layer 30 includes a first portion 30A and a second portion 30B. The first portion 30A is located under the deformable portion 10A, the second portion 30B is located under one of the main portions 10B, and a thickness T1 of the first portion 30A is less than a thickness T2 of the second portion 30B. In some embodiments, the electronic device 100 may be a bendable electronic device, a foldable electronic device, a flexible electronic device, and/or a stretchable electronic device. When the electronic device is bent, folded, flexed, and/or stretched, the deformable portion 10A of the flexible layer 10 and the medium layer 30 and the supporting layer 20 corresponding to the deformable portion 10A may be deformed. By thinning the medium layer 30 located corresponding to the deformable portion 10A, the risk of peeling between the supporting layer 20 and the flexible layer 10 during the deformation processes such as bending, folding, flexing, and/or stretching and/or after the deformation processes may be reduced and/or the stress between the supporting layer 20 and the flexible layer 10 during the deformation may be reduced, and the reliability of the electronic device may be improved accordingly.

As shown in FIG. 1A and FIG. 1B, in some embodiments, the electronic device 100 may have a folding axis AX, the electronic device 100 may be folded using the folding axis AX as the center, and the folding axis AX may overlap the deformable portion 10A. For example, the folding axis AX and the deformable portion 10A may overlap each other in a normal direction of the deformable portion 10A when the electronic device 100 is flattened (such as the condition illustrated in FIG. 1A). In addition, when the electronic device is folded, the deformable portion 10A of the flexible layer 10, the first portion 30A of the medium layer 30 located corresponding to the deformable portion 10A, and the portion of the supporting layer 20 located corresponding to the deformable portion 10A may be deformed for realizing the folded state. Relatively, at least a part of the main portion 20B of the flexible layer 20, at least a part of the second portion 30B of the medium layer 30, and at least a part of the portion of the supporting layer 20 located corresponding to the main portion 10B may not be deformed when the electronic device is folded, but not limited thereto. In some embodiments, the material of the flexible layer 10 may include polyimide (PI), polycarbonate (PC), polyethylene terephthalate (PET), other suitable materials, or combinations of the materials described above, and the material of the supporting layer 20 may include PI, PET, polydimethylsiloxane (PDMS), other suitable materials, or combinations of the materials described above, but not limited thereto. Additionally, the medium layer 30 may be used to connect the flexible layer 10 and the supporting layer 20 and alleviate the stress difference between the flexible layer 10 and the supporting layer 20 during the deformation process. For example, the material of the medium layer 30 may include but is not limited to optical clear adhesive (OCA), optical clear resin (OCR), and/or other suitable connecting materials.

It is worth noting that the thickness T1 of the first portion 30A and the thickness T2 of the second portion 30B of the medium layer 30 described above are thicknesses measured in the condition where the electronic device 100 is not bent, folded, flexed, and/or stretched. In some embodiments, the thickness T1 and the thickness T2 may be the thickness values obtained by measuring at any position on the first portion 30A and the second portion 30B which are more than 10 micrometers away from the interface between the first portion 30A and the second portion 30B, respectively. In some embodiments, the thickness T1 may be the minimum thickness of the first portion 30A in a vertical direction (such as a direction Z), and the thickness T2 may be the minimum thickness of the second portion 30B in this vertical direction, but not limited thereto. Additionally, in some embodiments, the electronic device 100 may further include a plurality of electronic elements (not illustrated in FIG. 1A and FIG. 1B) disposed on the main portions 10B. The electronic elements may include kinds of active elements and/or passive elements, such as light emitting elements (display elements, backlight elements, or other elements capable of emitting light, for example), sensing elements (elements for light sensors, biosensors, touch sensors, fingerprint sensors, other suitable sensors or combinations of the above-mentioned sensors, for example), antenna elements (such as liquid crystal antenna elements, but not limited thereto), and/or other suitable electronic elements. Therefore, the electronic device may include a display device, a backlight device, a sensor device, an antenna device, or other suitable electronic devices.

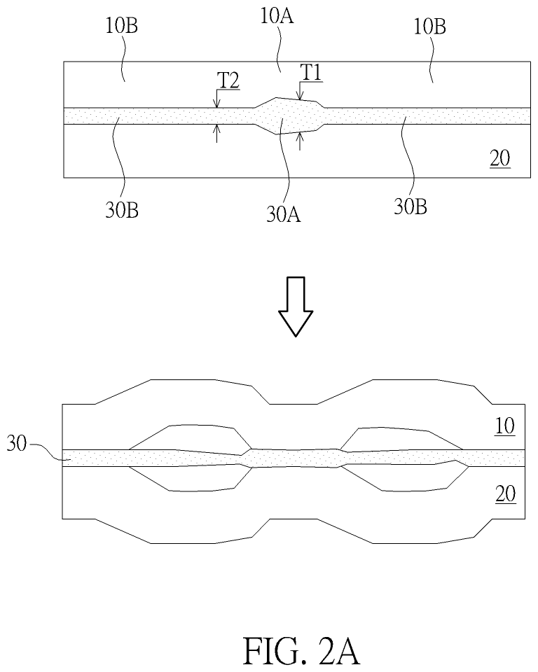

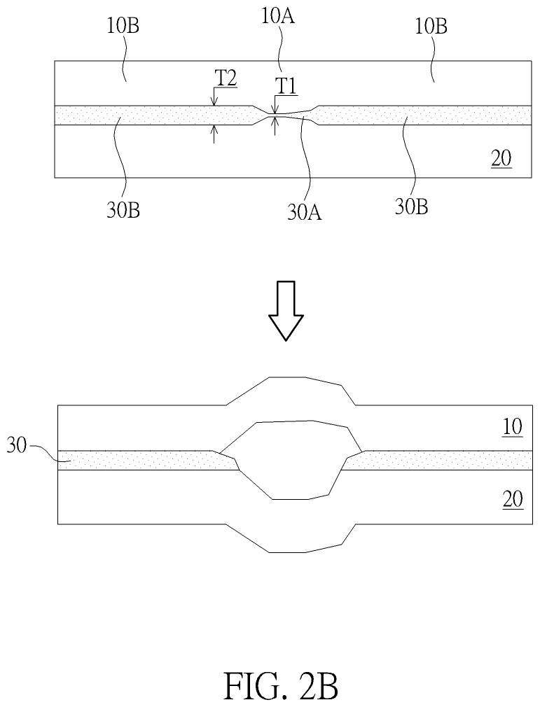

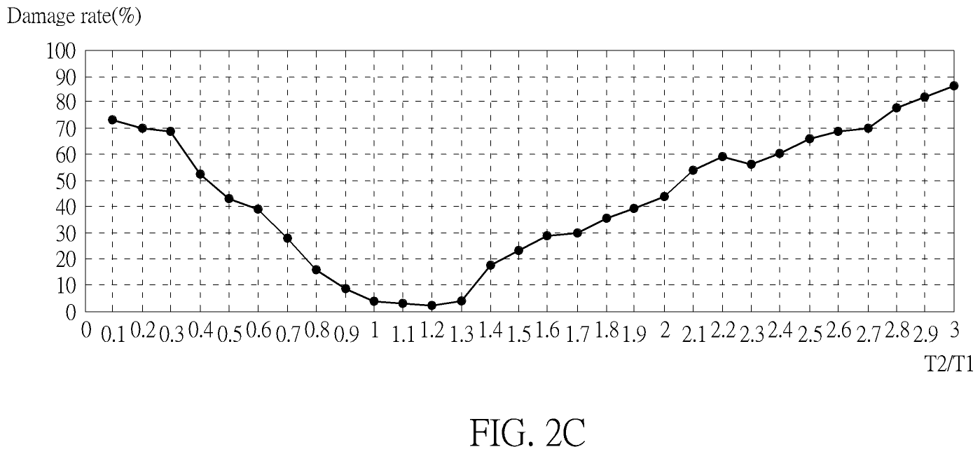

Please refer to FIG. 2A, FIG. 2B, and FIG. 2C. FIG. 2A is a schematic diagram illustrating an electronic device before and after deformation (such as being bent, folded, flexed, stretched, or deformed by other approaches) according to another embodiment of the present disclosure, FIG. 2B is a schematic diagram illustrating an electronic device before and after deformation according to further another embodiment of the present disclosure, and FIG. 2C is a schematic diagram of the relationship between a thickness design of the medium layer in the electronic device and damage rate according to an embodiment of the present disclosure. In FIG. 2A and FIG. 2B, the upper portions are the state before the deformation of the electronic device and the lower portions are the state after the deformation of the electronic device. In some embodiments, the condition after the deformation in FIG. 2A, FIG. 2B, and FIG. 2C may be a condition after multiple deformations (such as, but not limited to, more than 10,000 times), but not limited thereto. As shown in FIG. 2A, FIG. 2B, and FIG. 2C, when the ratio of the thickness T2 of the second portion 30B to the thickness T1 of the first portion 30A (T2/T1) is less than 1 or greater than 1.3, the damage rate of the electronic device after multiple deformations rises apparently. In FIG. 2A, the ratio of the thickness T2 of the second portion 30B to the thickness T1 of the first portion 30A (T2/T1) is greater than or equal to 0.1 and less than 1, and separation may occur easily between the flexible layer 10 and the supporting layer 20 with this thickness design after multiple deformations of the electronic device. In FIG. 2B, the ratio of the thickness T2 of the second portion 30B to the thickness T1 of the first portion 30A (T2/T1) is greater than 1.3 and less than or equal to 10, and separation may also occur easily between the flexible layer 10 and the supporting layer 20 with this thickness design after multiple deformations of the electronic device. In other words, the first portion 30A of the medium layer 30 may be thinner than the second portion 30B and the thickness difference between the first portion 30A and the second portion 30B may be kept within a specific range for reducing the chance of damage to the electronic device after undergoing multiple deformations. In some embodiments, such as in the electronic device 100 shown in FIG. 1A, the ratio of the thickness T2 of the second portion 30B to the thickness T1 of the first portion 30A (T2/T1) may be greater than or equal to 1 and less than or equal to 1.3, and the difference between the thickness T2 of the second portion 30B and the thickness T1 of the first portion 30A may be greater than or equal to 0.5 micrometers and less than or equal to 5 micrometers, but not limited thereto.

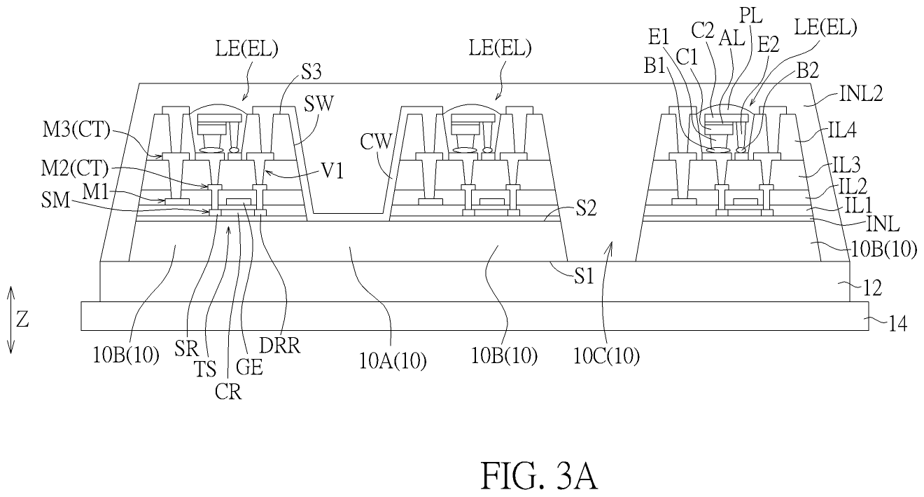

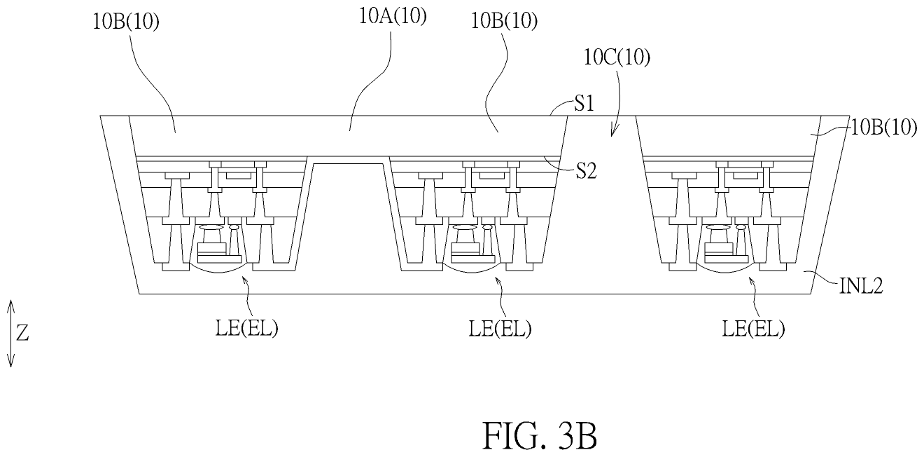

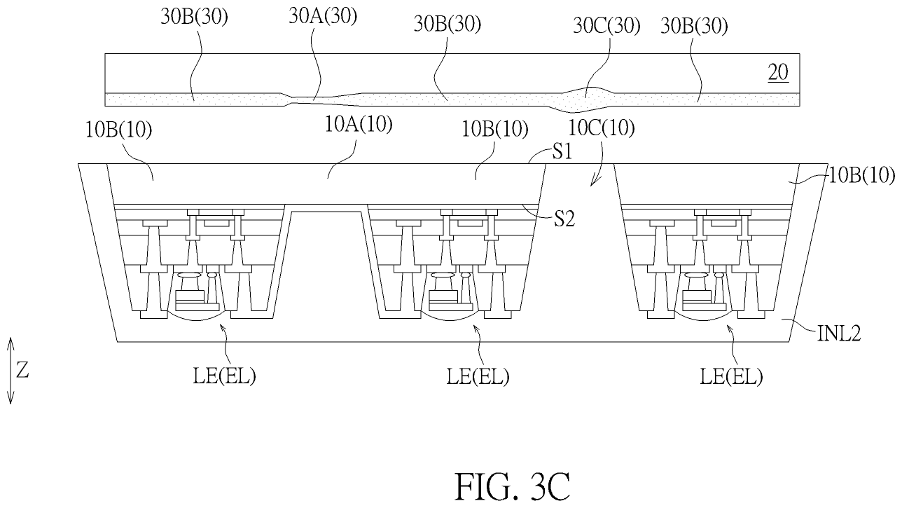

Please refer to FIG. 3A, FIG. 3B, and FIG. 3C. FIG. 3A, FIG. 3B, and FIG. 3C are schematic diagrams illustrating a manufacturing method of an electronic device according to a first embodiment of the present disclosure, wherein FIG. 3B is a schematic drawing in a step subsequent to FIG. 3A, and FIG. 3C is a schematic drawing in a step subsequent to FIG. 3B. In some embodiments, the manufacturing method of the electronic device may include but is not limited to the following steps. As shown in FIG. 3A, a carrier board 12 may be provided, and the carrier board 12 may include a rigid material for providing supporting effect or a flexible material, such as glass, metal board (such as stainless steel), non-metallic board (such as plastic), polyethylene terephthalate (PET), other suitable materials or combinations of the above-mentioned materials, but not limited thereto. In some embodiments, the carrier board 12 may be disposed on another substrate 14 for subsequent manufacturing processes, especially when the carrier board is a flexible material, but not limited thereto. Subsequently, the flexible layer 10 may be formed on the carrier board 12. The flexible layer 10 may have a surface S1 and a surface S2 opposite to the surface S1 in the direction Z, the surface S1 may be the surface adjacent to the carrier board 12, and the surface S2 may be the surface away from the carrier board. An insulation layer INL may then be formed on the surface S2 of the flexible layer 10, and a plurality of transistors TS may be formed on the insulation layer INL. For example, a semiconductor layer SM, an insulation layer IL1, and a metal layer M1 may be formed sequentially on the insulation layer INL, and a doping process may be performed to the semiconductor layer SM, wherein the metal layer M1 may be patterned, a part of the metal layer M1 may become a gate electrode GE of the transistor TS, the doped semiconductor layer SM may become a source region SR and a drain region DRR of the transistor TS, a channel region CR may exist between the source region SR and the drain region DRR, and the insulation layer IL1 may become a gate insulation layer of the transistor TS, but not limited thereto. It is noting that the transistor TS may be formed by any suitable manufacturing method according to the product design requirements, and this embodiment is not limited to this.

After the step of disposing the transistors TS on the insulation layer INL, contact elements CT may be formed on the transistors TS. For example, an insulation layer IL2, a metal layer M2, an insulation layer IL3, a metal layer M3, and an insulation layer IL4 may be formed sequentially on the metal layer M1, wherein a via hole V1 in the insulation layer IL3 may be filled with the metal layer M3, the metal layer M3 may be coupled with the metal layer M2, a via hole V2 in the insulation layer IL2 may be filled with the metal layer M2, and the metal layer M2 may be coupled with the source region SR and the drain region DRR of the transistor TS for forming the contact elements CT, but not limited thereto. Subsequently, electronic elements EL may be disposed, and the contact elements CT may be used to couple the transistor TS with the electronic element EL (such as a light emitting element LE) and/or a conductive wire CW. The following takes the electronic element EL including the light emitting element LE as an example for illustration, but the present embodiment is not limited to this. In some embodiments, the light emitting element LE may include a semiconductor layer C1, a semiconductor layer C2, an active layer AL located between the semiconductor layer C1 and the semiconductor layer C2, an electrode E1 connected with the semiconductor layer C1, and an electrode E2 connected with the semiconductor layer C2, but not limited thereto. In addition, the electrode E1 and the electrode E2 of the light emitting element LE may be coupled to the driving elements or other electronic elements in the electronic device respectively through a bonding material B1 and a bonding material B2. For example, the light emitting elements LE may be coupled to the transistors TS, and the light emission of the light emitting elements LE may be driven by the transistors TS, but not limited thereto. Furthermore, the electronic device in the present embodiment may further include a protecting layer PL, wherein the protecting layer PL may be disposed on the light emitting elements LE and cover the light emitting elements LE to provide protection, but not limited thereto.

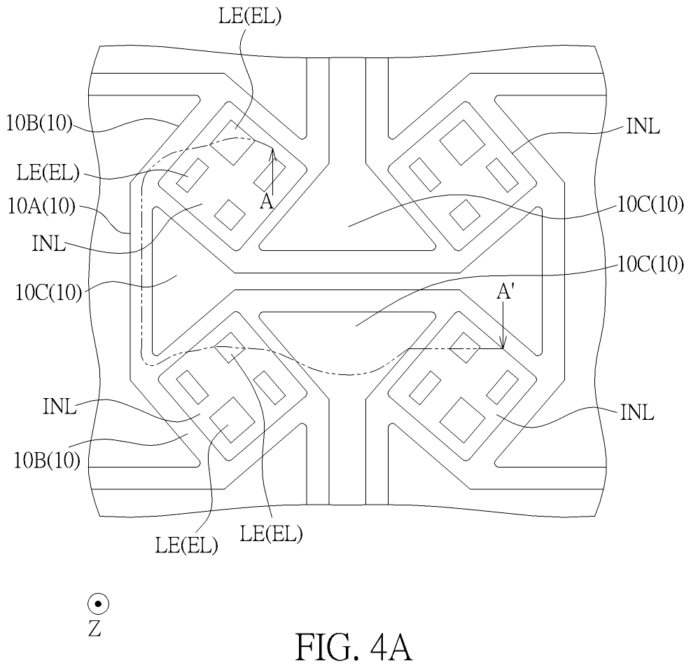

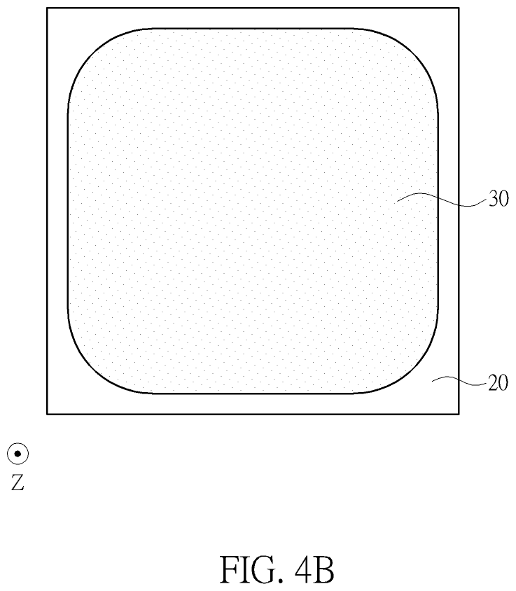

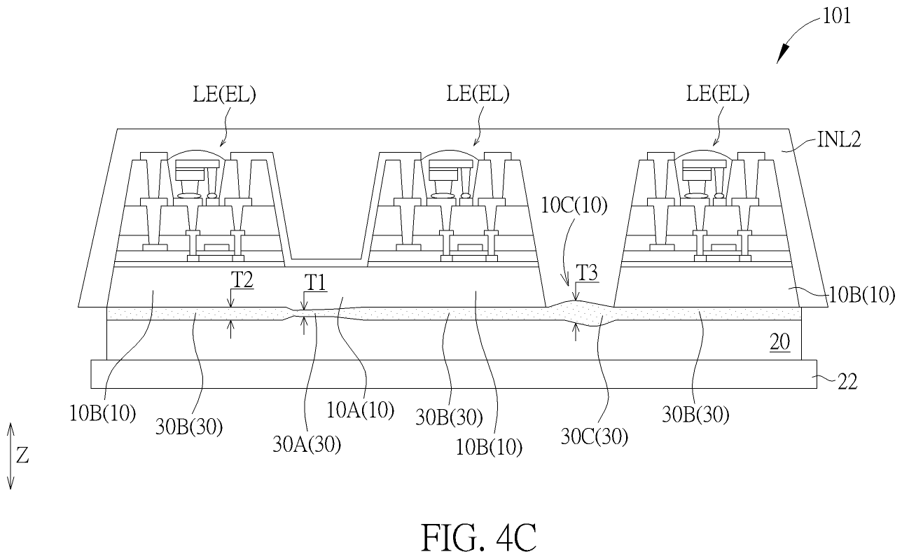

In some embodiments, the insulation layer IL4, the insulation layer IL3, the insulation layer IL2, and the insulation layer IL1 located above the deformable portion 10A may be removed b by a patterning process for separating the insulation layers INL, the transistors TS, and the electronic elements EL located above different main portions 10B, and the conductive wire CW may be formed after the patterning process described above. For instance, a part of the conductive wire CW may be formed on top surfaces of the insulation layers IL4 (i.e. top surfaces S3) on the two adjacent main portions 10B, and another part of the conductive wire CW may extend along sidewalls of the insulation layers to be located on the deformable portion 10A. A part of the conductive wire CW disposed on the insulation layer IL4 may penetrate through the insulation layer IL4 for being coupled with the contact element CT, and the conductive wire CW may be coupled with the transistors TS on the main portions 10B adjacent to each other via the contact elements CT, but not limited thereto. In some embodiments, the flexible layer 10 may further include a hollow region 10C, the hollow region 10C may be formed by removing a part of the flexible layer 10 located between the adjacent main portions 10B, and the part of the flexible layer 10 located between the adjacent main portions 10B may be removed by a removing process performed after the patterning process described above. Therefore, the hollow region 10C may be regarded as an excavated area in the flexible layer 10, but not limited thereto. In addition, after the step of disposing the conductive wire CW, an insulation layer INL2 may be disposed. The insulation layer INL2 may contact the flexible layer 10 and the carrier board 12 for packaging the layers and the electronic elements between the insulation layer INL2 and the carrier board 12 and providing protection. It is worth noting that the electronic elements and the corresponding circuits, material layers, and other related elements in the present disclosure are not limited to the condition illustrated in FIG. 3A described above, and other types of electronic elements and related parts may also be applied according to some design considerations. As shown in FIG. 3A and FIG. 3B, the carrier board 12 may be removed for exposing the surface S1 of the flexible layer 10. Subsequently, as shown in FIG. 3B and FIG. 3C, the supporting layer 20 with the medium layer 30 formed thereon may be bonded to the surface 51 of the flexible layer 10 for forming an electronic device 101 illustrated in FIG. 4C. It is worth noting that the manufacturing method of the electronic device 101 illustrated in FIG. 4C may include but is not limited to the above-mentioned steps illustrated in FIG. 3A, FIG. 3B, and FIG. 3C.

Please refer to FIG. 4A, FIG. 4B, and FIG. 4C. FIG. 4A is a top view schematic diagram illustrating a partial area of the electronic device according to the first embodiment of the present disclosure, and FIG. 4B is a top view schematic diagram illustrating the supporting layer and the medium layer of the electronic device in this embodiment. In some embodiments, FIG. 4C may be regarded as a cross-sectional schematic diagram of the electronic device in this embodiment taken along a line A-A′ in FIG. 4A, but not limited thereto. As shown in FIG. 4C, the electronic device 101 includes the supporting layer 20, the flexible layer 10, the medium layer 30, and the electronic elements EL. The electronic elements EL may be disposed on the main portions 10B, respectively, and the thickness T1 of the first portion 30A of the medium layer 30 located corresponding to the deformable portion 10A is less than the thickness T2 of the second portion 30B of the medium layer 30 located corresponding to the main portions 10B. Additionally, in some embodiments, the supporting layer 20 may be disposed on another substrate 22 for carrying out other manufacturing processes, but not limited thereto. As shown in FIG. 4A, FIG. 4B, and FIG. 4C, in some embodiments, the medium layer 30 may be a whole layer structure disposed on the supporting layer 20 without patterned features located corresponding to the flexible layer 10. Additionally, the flexible layer 10 may further include the hollow region 10C disposed adjacent to the deformable portion 10A and/or the main portions 10B. The medium layer 30 may further include a third portion 30C located under the hollow region 10C, and a thickness T3 of the third portion 30C may be greater than the thickness T2 of the second portion 30B. In some embodiments, the thickness T3 of the third portion 30C may be the thickness value obtained by measuring at any position on the third portion 30C which is more than 10 micrometers away from the interface between the second portion 30B and the third portion 30C. In some embodiments, the thickness T3 may be the maximum thickness of the third portion 30C in the direction Z, but not limited thereto. The peeling off risk of the supporting layer 20 during and/or after the deformation may be further reduced by the relatively thick third portion 30 located corresponding to the hollow region 10C. In some embodiments, the ratio of the thickness T2 of the second portion 30B to the thickness T3 of the third portion 30C (T2/T3) may be greater than 0.7 and less than 1 for achieving the performance described above, but not limited thereto. As shown in FIG. 4A and FIG. 4C, in some embodiments, a plurality of the light emitting elements LE may be disposed on one main portion 10B and emit light of different colors, and the light of different colors may be mixed to produce the desired color, but not limited thereto. For example, the light emitting elements LE disposed on one main portion 10B may emit red light, green light, and blue light, respectively, and the red light, the green light, and the blue light may be mixed to produce white light, but not limited thereto. In some embodiments, there may be only one light emitting element LE disposed on one main portion 10B. It is worth noting that the arrangement of the light emitting elements LE illustrated in FIG. 4A is exemplary only, and the present embodiment is not limited to this.

The electronic device of the present disclosure is not limited to the above-mentioned embodiments and may have different embodiments. In order to simplify the description, the different embodiments below use the same reference numerals to denote the same elements as the above-mentioned embodiments. In order to clearly illustrate the different embodiments, the following description focuses on differences between the embodiments, and same parts will not be repeated again.

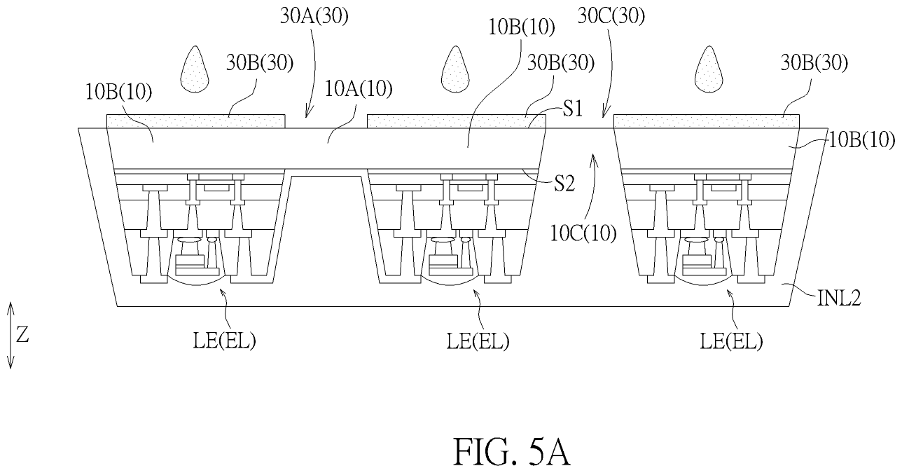

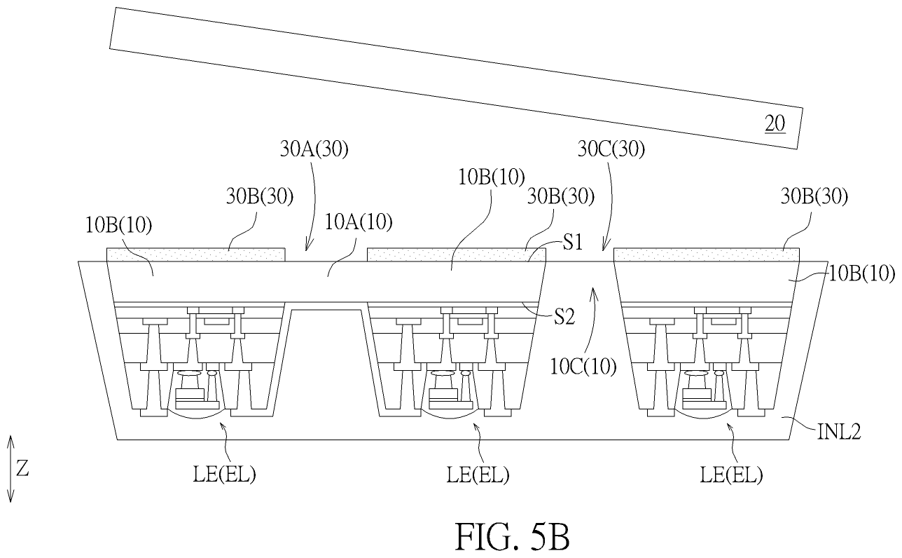

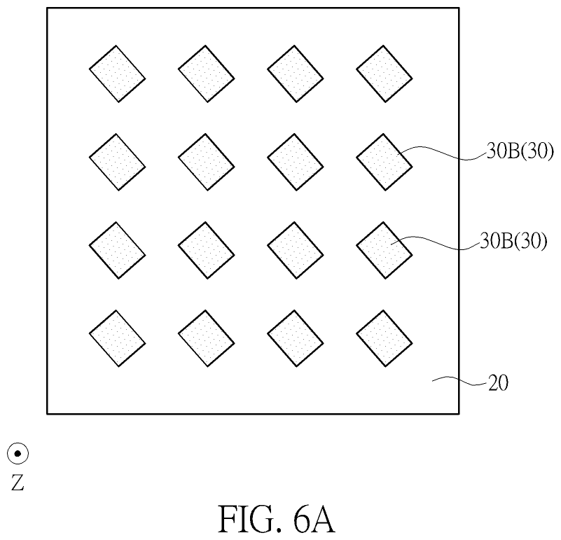

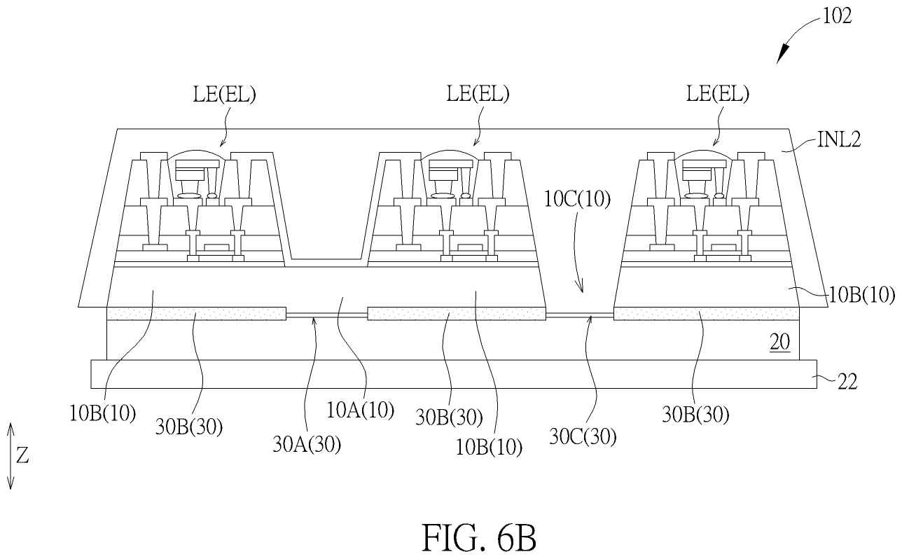

Please refer to FIG. 5A, FIG. 5B, FIG. 6A, and FIG. 6B, and refer to FIG. 3A and FIG. 3B also. FIG. 5A and FIG. 5B are schematic diagrams illustrating a manufacturing method of an electronic device according to a second embodiment of the present disclosure, wherein FIG. 5B is a schematic drawing in a step subsequent to FIG. 5A. FIG. 6A is a top view schematic diagram illustrating the supporting layer and the medium layer of the electronic device in this embodiment, and FIG. 6B is a cross-sectional schematic diagram of the electronic device in this embodiment. In some embodiments, FIG. 5A may be regarded as a schematic drawing in a step subsequent to FIG. 3B, but not limited thereto. In this embodiment, the manufacturing method of the electronic device may include but is not limited to the following steps. As shown in FIG. 3A, FIG. 3B, and FIG. 5A, after the step of removing the carrier board 12 and exposing the surface S1 of the flexible layer 10, the medium layer 30 corresponding to the main portions 10B may be formed on the surface S1 of the flexible layer 10, and the medium layer 30 is not formed above the deformable portion 10A and the hollow region 10C. In some embodiments, only the second portion 30B of the medium layer 30 may be formed, and the second portion 30B of the medium layer 30 may be formed by a specific process (such as an ink-jet process, but not limited thereto), or a patterning process (such as a photolithographic process, but not limited thereto) may be performed after the step of forming the medium layer 30 entirely for removing a part of the medium layer 30. As shown in FIG. 5A and FIG. 5B, after the step of forming the medium layer 30 on the surface S1 of the flexible layer 10, the supporting layer 20 and the medium layer 30 may be bonded to the flexible layer 10 for forming an electronic device 102 illustrated in FIG. 6B. It is worth noting that the manufacturing method of the electronic device 102 illustrated in FIG. 6B may include but is not limited to the steps illustrated in FIG. 5A and FIG. 5B described above. As shown in FIG. 6A and FIG. 6B, in the electronic device 102, the second portions 30B of the medium layer 30 located corresponding to the main portions 10B may be disposed and arranged on the supporting layer 20 and separated from one another. In other words, the first portion 30A of the medium layer 30 located corresponding to the deformable portion 10A and the third portion 30C of the medium layer 30 located corresponding to the hollow region 10C may be regarded as regions with zero thickness in the medium layer 30, and the thickness of the first portion 30A of the medium layer 30 and the thickness of the third portion 30C of the medium layer 30 may be less than the thickness of the second portion 30B of the medium layer 30.

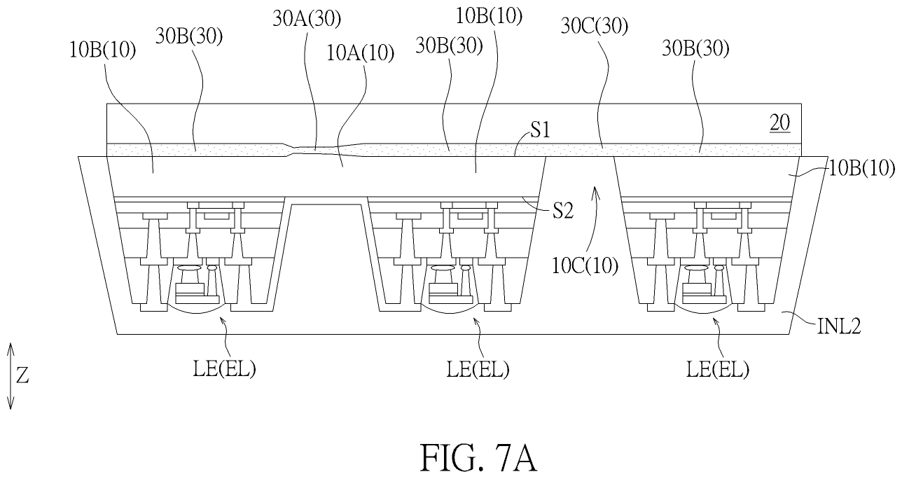

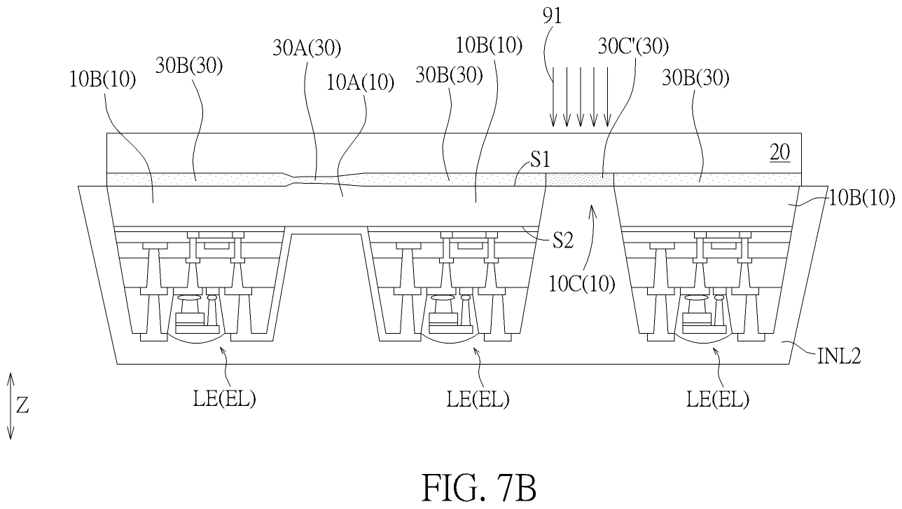

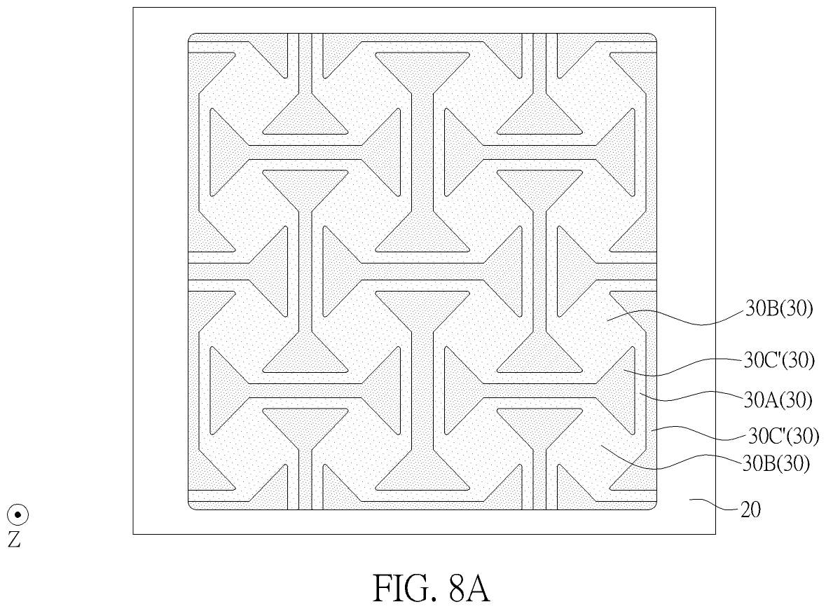

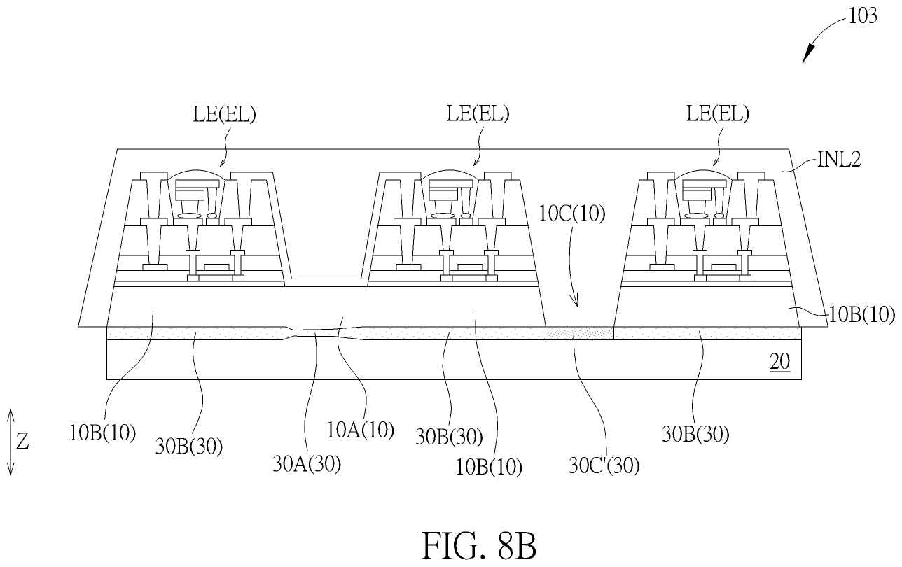

Please refer to FIG. 7A, FIG. 7B, FIG. 8A, and FIG. 8B, and refer to FIG. 3A and FIG. 3B also. FIG. 7A and FIG. 7B are schematic diagrams illustrating a manufacturing method of an electronic device according to a third embodiment of the present disclosure, wherein FIG. 7B is a schematic drawing in a step subsequent to FIG. 7A. FIG. 8A is a top view schematic diagram illustrating the supporting layer and the medium layer of the electronic device in this embodiment, and FIG. 8B is a cross-sectional schematic diagram of the electronic device in this embodiment. In some embodiments, FIG. 7A may be regarded as a schematic drawing in a step subsequent to FIG. 3B, but not limited thereto. As shown in FIG. 3A, FIG. 3B, and FIG. 7A, after the step of removing the carrier board 12 and exposing the surface S1 of the flexible layer 10, the supporting layer 20 with the medium layer 30 formed thereon may be bonded to the surface S1 of the flexible layer 10. Subsequently, as shown in FIG. 7A and FIG. 7B, a modification treatment 91 may be performed to the third portion 30C of the medium layer 30 located under the hollow region 10C for adjusting the material characteristics of the third portion 30C and forming an electronic device 103 illustrated in FIG. 8B. It is worth noting that the manufacturing method of the electronic device 103 illustrated in FIG. 8B may include but is not limited to the steps illustrated in FIG. 7A and FIG. 7B described above. In some embodiments, the modification treatment 91 may include an ultraviolet (UV) irradiation treatment for reducing the viscosity of the third portion 30C. In other words, the third portion 30C of the medium layer 30 may be converted into a treated third portion 30C′ located under the hollow region 10C by the modification treatment 91, and the viscosity of the treated third portion 30C′ is lower than the viscosity of the first portion 30A of the medium layer 30 and the viscosity of the second portion 30B of the medium layer 30. In addition, the modification treatment 91 in this disclosure is not limited to the UV irradiation treatment described above and may be other treatment approach for adjusting the viscosity and/or other characteristics of the medium layer 30 according to some design considerations. As shown in FIG. 8A and FIG. 8B, in the electronic device 103, the pattern shapes of the first portion 30A and the second portion 30B of the medium layer 30 in the top view direction may be identical or similar to that of the deformable portion 10A and the main portion 10B of the flexible layer 10, and the treated third region 30C′ of the medium layer 30 may be located corresponding to the hollow region 10C of the flexible layer 10 in the direction Z. The peeling off risk of the supporting layer 20 during and/or after the deformation may be reduced by reducing the viscosity of the medium layer 30 located corresponding to the hollow region 10C of the flexible layer 10, and that is beneficial for the reliability of the electronic device.

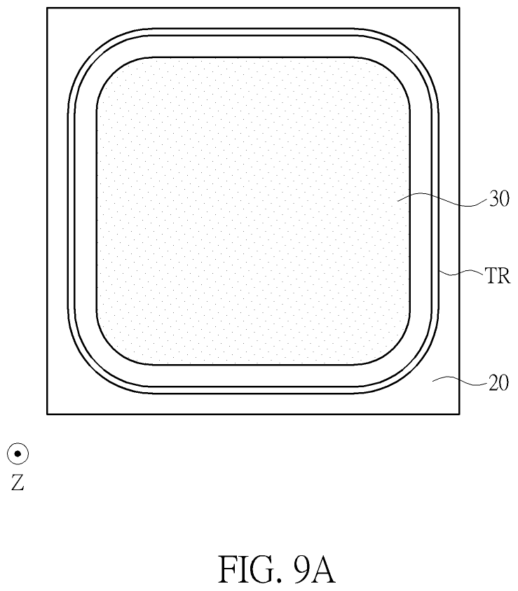

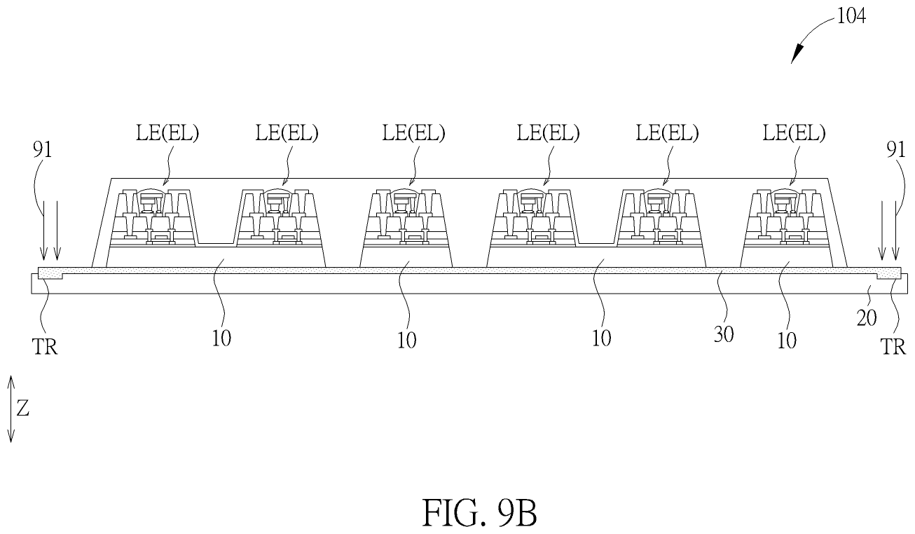

Please refer to FIG. 9A and FIG. 9B. FIG. 9A is a top view schematic diagram illustrating the supporting layer and the medium layer of the electronic device according to a fourth embodiment of the present disclosure, and FIG. 9B is a schematic diagram illustrating a manufacturing method of the electronic device 104 in this embodiment. As shown in FIG. 9A, in some embodiments, the supporting layer 20 may include a trench TR, the trench TR may be a groove without penetrating through the supporting layer 20, and the trench TR may completely surround or surround at least a portion of the medium layer 30 when viewed in the top view direction of the flexible electronic device. As shown in FIG. 9B, in some embodiments, the trench TR and the medium layer 30 may be located at the same side of the supporting layer 20, and the trench TR may be regarded as a detention pond for the medium layer 30. When the medium layer 30 overflows outward during the manufacturing process of the electronic device, the trench TR may accommodate the overflowed medium layer 30 and improve the overflow issue of the medium layer 30. Additionally, in some embodiments, the modification treatment 91 described above may be performed to the medium layer 30 located in the trench TR for reducing the viscosity of the overflowed medium layer 30, for example, and related issues generated by the overflowed medium layer 30 may be improved accordingly, but not limited thereto. In addition, the trench TR in this embodiment may also be applied to other embodiments of the present disclosure according to some design considerations.

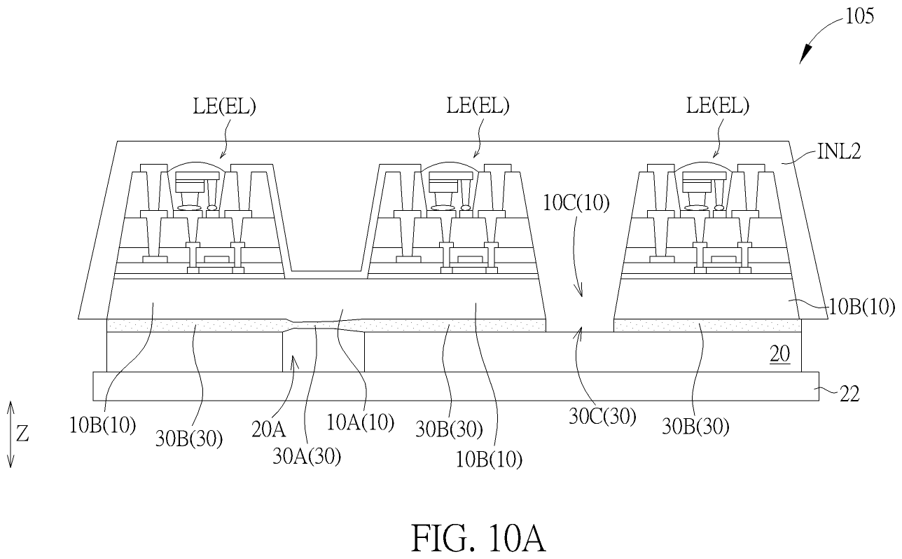

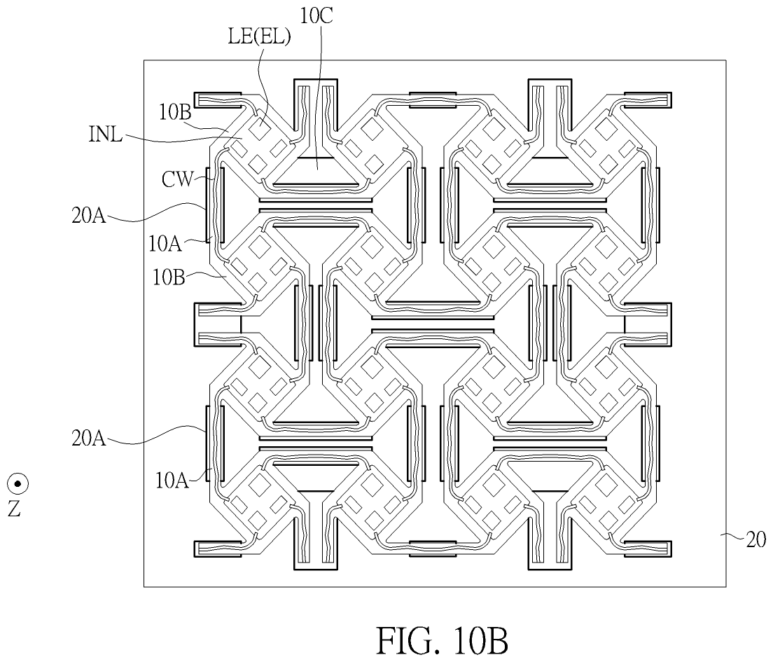

Please refer to FIG. 10A and FIG. 10B. FIG. 10A is a cross-sectional schematic diagram of an electronic device according to a fifth embodiment of the present disclosure, and FIG. 10B is a top view schematic diagram illustrating the electronic device in this embodiment. As shown in FIG. 10A and FIG. 10B, in an electronic device 105, the supporting layer 20 may include an opening 20A located under the deformable portion 10A, and the opening 20A may penetrate through the supporting layer 20 in the direction Z. The opening 20A may be used to reduce the friction between the supporting layer 20 and the deformable portion 10A with the conductive wire CW disposed thereon during the deformations, and that is beneficial for the reliability of the electronic device. In addition, the opening 20A in the supporting layer 20 of the present embodiment may also be applied to other embodiments of the present disclosure according to some design considerations.

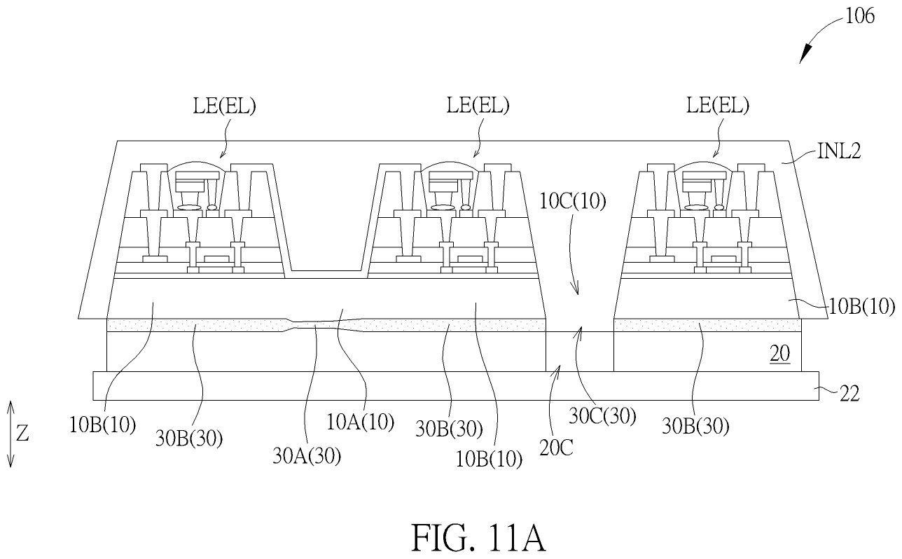

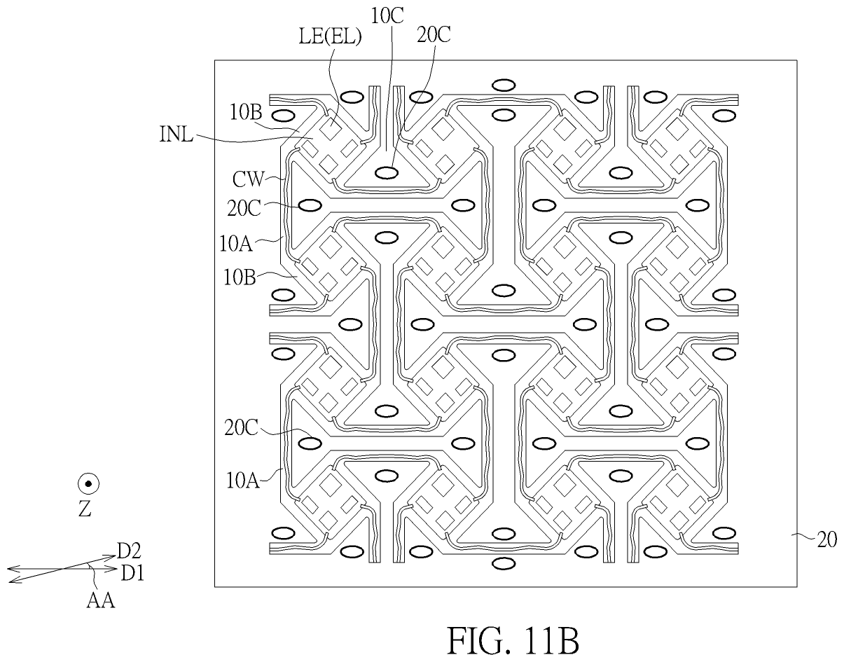

Please refer to FIG. 11A and FIG. 11B. FIG. 11A is a cross-sectional schematic diagram of an electronic device according to a sixth embodiment of the present disclosure, and FIG. 11B is a top view schematic diagram illustrating the electronic device in this embodiment. As shown in FIG. 11A and FIG. 11B, in an electronic device 106, the supporting layer 20 may include an opening 20C located under the hollow region 10C, the opening 20C may penetrate through the supporting layer 20 in the direction Z, and the opening 20C may not overlap the deformable portion 10A and the main portion 10B in the direction Z. In some embodiments, an acute angle AA between a longitudinal direction of the opening 20C (such as a direction D1 illustrated in FIG. 11B) and a stretching direction of the electronic device 106 (such as a direction D2 illustrated in FIG. 11B) may be greater than or equal to 0 degree and less than or equal to 30 degrees, that is beneficial for stretching the electronic device 106, and the stretchability of the electronic device 106 may be improved accordingly. In some embodiments, the longitudinal direction of the opening 20C may be defined in terms of the direction of extension of the line connecting the two furthest points on the edge of the opening 20C, and the stretching direction of the electronic device may be regarded as the direction in which the electronic device elongates and contracts during normal stretching operations, but not limited thereto. In addition, the opening 20C in the supporting layer of the present embodiment may also be applied to other embodiments of the present disclosure according to some design considerations.

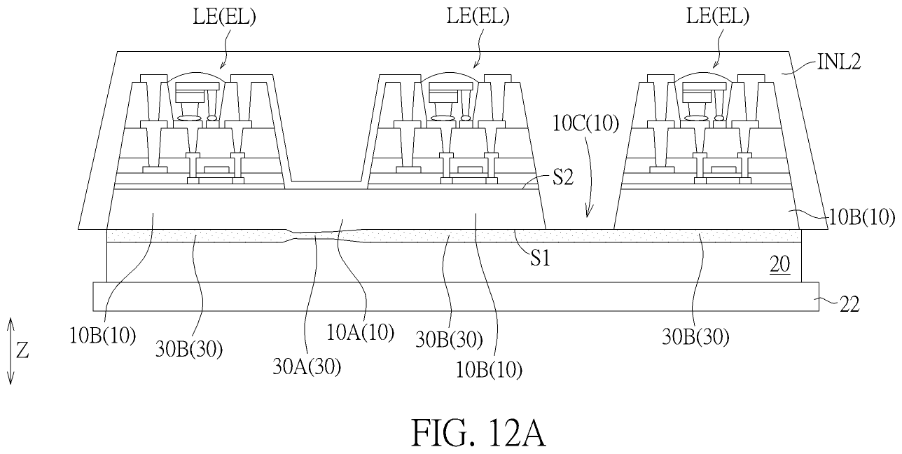

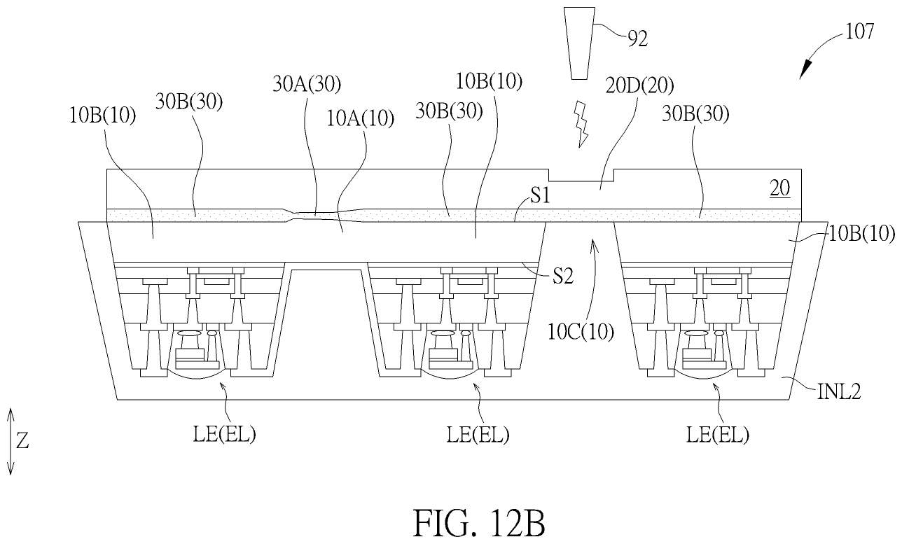

Please refer to FIG. 12A and FIG. 12B, and refer to FIG. 3A and FIG. 3B also. FIG. 12A and FIG. 12B are schematic diagrams illustrating a manufacturing method of an electronic device according to a seventh embodiment of the present disclosure, wherein FIG. 12B is a schematic drawing in a step subsequent to FIG. 12A. In some embodiments, FIG. 12A may be regarded as a schematic drawing in a step subsequent to FIG. 3B, but not limited thereto. As shown in FIG. 3A, FIG. 3B, and FIG. 12A, after the step of removing the carrier board 12 and exposing the surface S1 of the flexible layer 10, the supporting layer 20 with the medium layer 30 formed thereon may be bonded to the surface S1 of the flexible layer 10. Subsequently, as shown in FIG. 12A and FIG. 12B, the substrate 22 may be removed for exposing the bottom surface of the supporting layer 20, and a removing treatment 92 may be performed to the supporting layer 20 located corresponding to the hollow region 10C in the direction Z at the side of the bottom surface of the supporting layer 20, so as to remove a part of the supporting layer 20 and form a thinned portion 20D. In other words, in the electronic device 107, the supporting layer 20 may include the thinned portion 20D located under the hollow region 10C, and the thickness of the thinned portion 20D may be less than the thickness of the supporting layer 20 located under the deformable portion 10A and the main portion 10B. In some embodiments, the removing treatment 92 may include a laser treatment, an etching treatment, or other suitable removing approaches, and the thinned portion 20D disposed corresponding to the hollow region 10C may be used to improve the stretchability of the electronic device 107. In addition, the thinned portion 20D in the supporting layer 20 of the present embodiment may also be applied to other embodiments of the present disclosure according to some design considerations.

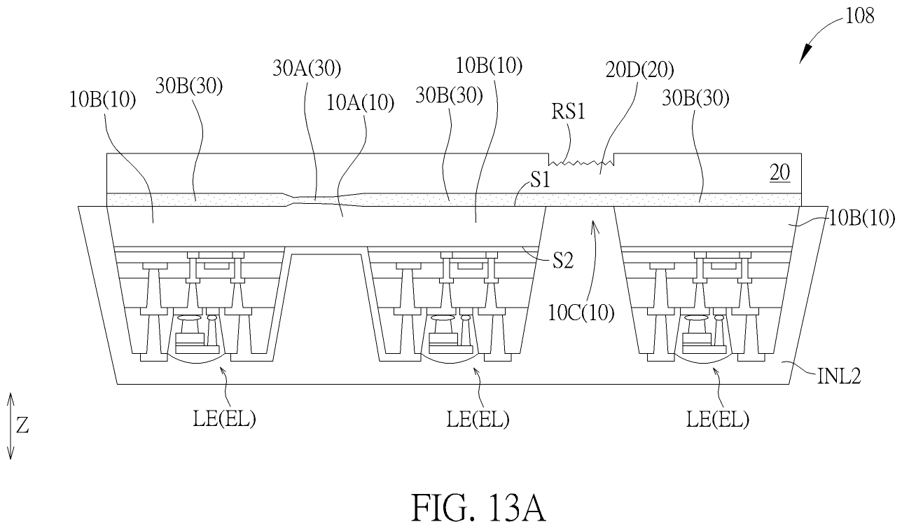

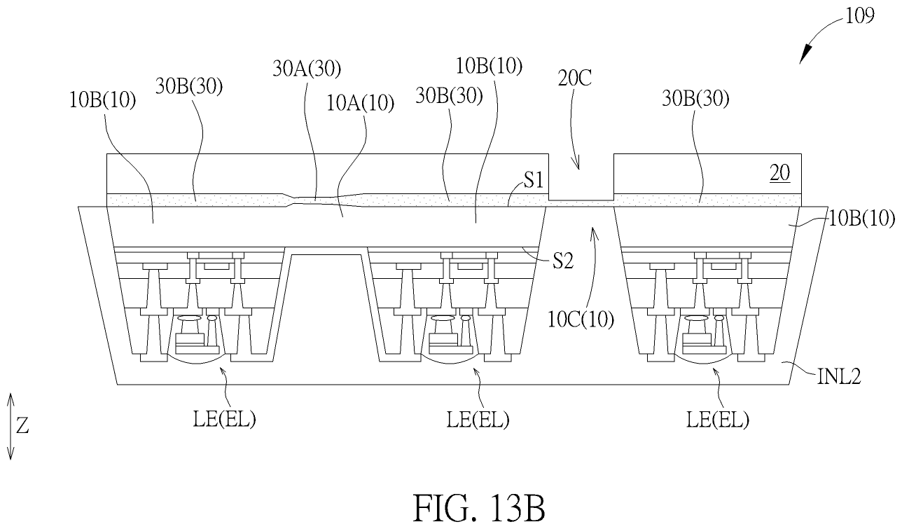

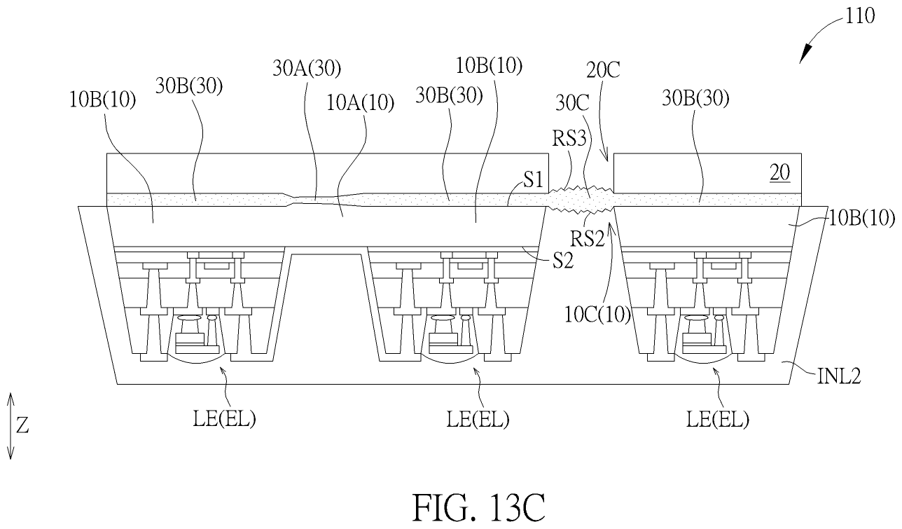

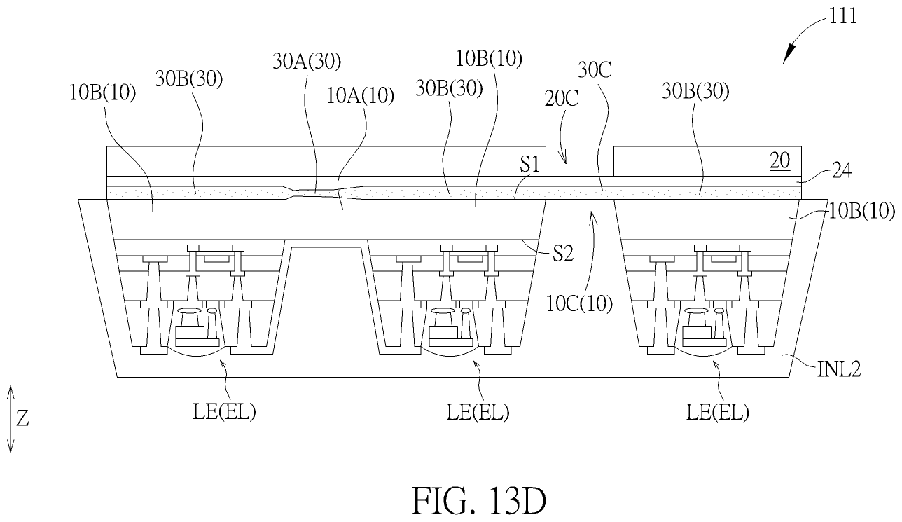

Please refer to FIG. 13A. FIG. 13A is a cross-sectional schematic diagram of an electronic device 108 according to an eighth embodiment of the present disclosure. As shown in FIG. 13A, in the electronic device 108, the thinned portion 20D of the supporting layer 20 may have a surface RS1, the surface RS1 may be a surface of the thinned portion 20D away from the medium layer 30 in the direction Z, and the roughness of the surface RS1 may be higher than the roughness of the bottom surface of the supporting layer 20 located under the deformable portion 10A and the main portion 10B. In some embodiments, the above-mentioned roughness design of the surface RS1 may be used to inspect and/or confirm the condition of the thinned portion 20D (such as the distribution of the thinned portion 20D, but not limited thereto), and the surface RS1 of the thinned portion 20D may be formed by the removing treatment 92 in the seventh embodiment described above and/or other suitable treating approaches. Additionally, in some embodiments, in order to measure the roughness of a surface, a region may be chosen in the cross-sectional view of the surface, and a plurality of high points (such as three high points, but not limited thereto) and a plurality of low points (such as three low points, but not limited thereto) of the surface may be selected in the region, wherein the roughness of the surface may for example be defined as the average of the height differences between the selected high points and low points, but not limited thereto. The cross-sectional view of the surface may for example be obtained through the scanning electron microscope (SEM), but not limited thereto. In addition, the surface RS1 of the thinned portion 20D in the present embodiment may also be applied to other embodiments of the present disclosure according to some design considerations.

Please refer to FIG. 13B. FIG. 13B is a cross-sectional schematic diagram of an electronic device 109 according to a ninth embodiment of the present disclosure. As shown in FIG. 13B, in the electronic device 109, the supporting layer 20 may include the opening 20C located under the hollow region 10C, the opening 20C may penetrate through the supporting layer 20 in the direction Z, and the opening 20C may be used to improve the stretchability of the electronic device 109. Additionally, in some embodiments, the opening 20C may be formed by the removing treatment 92 in the seventh embodiment described above and/or other suitable treating approaches, and a part of the medium layer 30 located between the opening 20C and the hollow region 10C may be removed by the treatment described above also, but not limited thereto.

Please refer to FIG. 13C. FIG. 13C is a cross-sectional schematic diagram of an electronic device 110 according to a tenth embodiment of the present disclosure. As shown in FIG. 13C, in the electronic device 110, the third portion 30C of the medium layer 30 may be located under the hollow region 10C, and the surface roughness of the third portion 30C may be greater than the surface roughness of the second portion 30B. For example, a surface RS2 of the third portion 30C of the medium layer 30 facing the hollow region 10C and a surface RS3 of the third portion 30C away from the hollow region 10C may be relatively rough surfaces, the rough surface RS2 may be used to improve the adhesion of the medium layer 30, and the rough surface RS3 may be used to inspect and/or confirm the condition of the opening 20C. In addition, the surface RS2 and/or the surface RS3 of the third portion 30C in the present embodiment may also be applied to other embodiments of the present disclosure according to some design considerations.

Please refer to FIG. 13D. FIG. 13D is a cross-sectional schematic diagram of an electronic device 111 according to an eleventh embodiment of the present disclosure. As shown in FIG. 13D, the electronic device 111 may further include an etching stop layer 24 disposed between the supporting layer 20 and the medium layer 30 for avoiding damage to other layers in the manufacturing process of the opening 20C (such as the removing treatment 92 in the seventh embodiment described above, but not limited thereto). In some embodiments, the material of the etching stop layer 24 may include metal (such as copper, titanium, aluminum, and so forth, but not limited thereto), metal oxide (such as zirconium oxide, zinc oxide, and so forth, but not limited thereto), or other materials having higher etching selectivity with the supporting layer 20. In addition, the etching stop layer 24 in the present embodiment may also be applied to other embodiments of the present disclosure according to some design considerations.

The feature of above-mentioned embodiments may be mixed and matched arbitrarily as long as there is no violation to the spirit of the invention or conflict between the features.

To summarize the above descriptions, in the electronic device according to the present disclosure, the design of the medium layer having different thickness may be used to reduce the risk of peeling between the supporting layer and the flexible layer during and/or after the deformation processes, and the product reliability of the electronic device may be improved accordingly.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. A flexible electronic device, comprising:
a supporting layer;
a flexible layer disposed on the supporting layer, wherein the flexible layer comprises at least two main portions and a deformable portion connecting the at least two main portions;
a medium layer disposed between the supporting layer and the flexible layer, wherein the medium layer comprises:
a first portion located under the deformable portion; and
a second portion located under one of the at least two main portions; and
electronic elements disposed on the at least two main portions,
wherein a thickness of the first portion is less than a thickness of the second portion.

2. The flexible electronic device according to claim 1, wherein the flexible electronic device has a folding axis overlapping the deformable portion.

3. The flexible electronic device according to claim 1, wherein a ratio of the thickness of the second portion to the thickness of the first portion is greater than 1 and less than or equal to 1.3.

4. The flexible electronic device according to claim 1, wherein a difference between the thickness of the second portion and the thickness of the first portion is greater than or equal to 0.5 micrometers and less than or equal to 5 micrometers.

5. The flexible electronic device according to claim 1, wherein the flexible layer further comprises a hollow region disposed adjacent to the deformable portion.

6. The flexible electronic device according to claim 5, wherein the medium layer further comprises a third portion located under the hollow region, and a thickness of the third portion is greater than the thickness of the second portion.

7. The flexible electronic device according to claim 5, wherein the supporting layer comprises an opening located under the hollow region.

8. The flexible electronic device according to claim 7, wherein the medium layer further comprises a third portion located under the hollow region, and a surface roughness of the third portion is greater than a surface roughness of the second portion.

9. The flexible electronic device according to claim 5, wherein the supporting layer comprises a thinned portion located under the hollow region.

10. The flexible electronic device according to claim 1, wherein the supporting layer comprises a trench, and the trench surrounds at least a portion of the medium layer when viewed in a top view direction of the flexible electronic device.

11. The flexible electronic device according to claim 10, wherein the trench and the medium layer are located at the same side of the supporting layer.

12. The flexible electronic device according to claim 1, wherein the supporting layer comprises an opening, and an acute angle between a longitudinal direction of the opening and a stretching direction of the flexible electronic device is greater than or equal to 0 degree and less than or equal to 30 degrees.

13. The flexible electronic device according to claim 1, wherein the supporting layer comprises an opening located under the deformable portion.

14. The flexible electronic device according to claim 1, further comprising:
an etching stop layer disposed between the supporting layer and the medium layer.

15. The flexible electronic device according to claim 1, wherein the electronic elements comprise light emitting elements, sensing elements or antenna elements.
